(19) United States
(12) Patent Application Publication
(10) Pub. No.: US 2009/0242878 A1
(43) Pub. Date: Oct. 1, 2009

(54) OPTIMIZATION OF NEW POLYMER SEMICONDUCTORS FOR BETTER MOBILITY AND PROCESSIBALITY

(75) Inventors: Hualong Pan, Ottawa (CA); Yuning Li, Mississaugua (CA); Yilang Wu, Mississaugua (CA); Ping Liu, Mississaugua (CA)

Correspondence Address: MH2 TECHNOLOGY LAW GROUP, LLP (CUST. NO. W/XEROX), 1951 KIDWELL DRIVE, SUITE 550, TYSONS CORNER, VA, 22182, US

(73) Assignee: Xerox Corporation, Norwalk, CT (US)

(21) Appl. No.: 12/056,548

(22) Filed: Mar. 27, 2008

(51) Int. Cl. H01L 51/05; C08G 75/06; B32B 27/00

(52) U.S. Cl. 257/40; 528/380; 528/379; 428/704; 257/E51.006

(57) ABSTRACT

In accordance with the invention, there are polymers (II) having the formula:

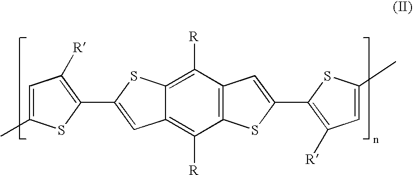

wherein R and R′ are substituents comprising about 8 to about 16 carbon atoms and n represents the number of repeat unit from about 5 to about 5000; and electronic devices, such as, for example, thin film transistors including the polymer (II).

### FIELD OF THE INVENTION

The present invention relates to polymer semiconductors and more particularly to the optimization of polymer semiconductors for better mobility and processability.

### BACKGROUND OF THE INVENTION

Polymer semiconductors are potentially important as channel materials for organic thin film transistors. Polymer semiconductors provide low cost alternative to silicon based transistors primarily due to the low cost fabrication using solution based deposition techniques, such as spin coating, inkjet printing, etc. To achieve low-cost roll-to-roll processing, polymer semiconductors requiring no post-deposition thermal annealing step are desired. U.S. patent application Ser. No. 11/586,449 by Ong, B. S., et al. disclosed poly(dithienylbenzo[1,2-b:4,5-b′]dithiophene)s or poly(bithiophene-benzo[1,2-b-4,5-b′]dithiophene)s (PBBDT), which can be solution processed as semiconductors for thin-film transistors without thermal annealing. However, most of this type of polymers have their poor solubility in common solvent due to their rigid backbones. Therefore TFT devices showed relatively low mobility and poor reproducibility due to poor film uniformity. Another issue is that the yield of polymers was low (in the range of about 10%).

Accordingly, there is a need to overcome these and other problems of prior art to provide poly(dithienylbenzo[1,2-b:4,5-b′]dithiophene)s semiconductors with optimized solubility, mobility, and yield.

### SUMMARY OF THE INVENTION

In accordance with various embodiments, there is a polymer (II) having the formula:

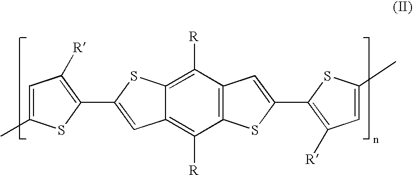

wherein R and R′ can be substituents including about 8 to about 16 carbon atoms and n represents the number of repeat unit from about 5 to about 5000.

According to various embodiments, there is an electronic device including a polymer (II) having the formula:

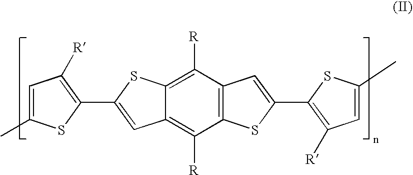

wherein R and R′ can be substituents including about 8 to about 16 carbon atoms and n represents the number of repeat unit from about 5 to about 5000.

According to another embodiment, there is a thin film transistor including a substrate, a dielectric layer disposed over the substrate, a source electrode and a drain electrode disposed over the substrate, and a semiconductor layer disposed over the substrate, the semiconductor layer including a polymer (II) having the formula:

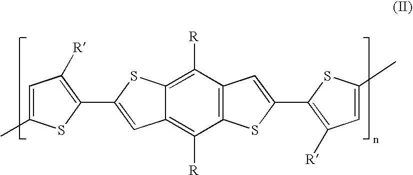

wherein R and R′ can be substituents including about 8 to about 16 carbon atoms and n represents the number of repeating groups of from about 5 to about 5000.

Additional advantages of the embodiments will be set forth in part in the description which follows, and in part will be obvious from the description, or may be learned by practice of the invention. The advantages will be realized and attained by means of the elements and combinations particularly pointed out in the appended claims.

It is to be understood that both the foregoing general description and the following detailed description are exemplary and explanatory only and are not restrictive of the invention, as claimed.

The accompanying drawings, which are incorporated in and constitute a part of this specification, illustrate embodiments of the invention and together with the description, serve to explain the principles of the invention.

### BRIEF DESCRIPTION OF THE DRAWINGS

FIGS. 1-4 illustrate exemplary thin film transistors, according to various embodiments of the present teachings.

### DESCRIPTION OF THE EMBODIMENTS

Reference will now be made in detail to the present embodiments, examples of which are illustrated in the accompanying drawings. Wherever possible, the same reference numbers will be used throughout the drawings to refer to the same or like parts.

Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements. Moreover, all ranges disclosed herein are to be understood to encompass any and all sub-ranges subsumed therein. For example, a range of “less than 10” can include any and all sub-ranges between (and including) the minimum value of zero and the maximum value of 10, that is, any and all sub-ranges having a minimum value of equal to or greater than zero and a maximum value of equal to or less than 10, e.g., 1 to 5. In certain cases, the numerical values as stated for the parameter can take on negative values. In this case, the example value of range stated as “less that 10” can assume negative values, e.g. −1, −2, −3, −10, −20, −30, etc.

According to various embodiments, there is a polymer (II) having the

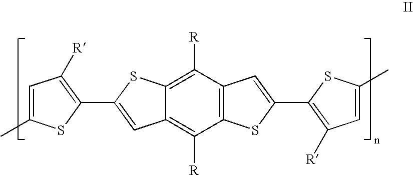

wherein R and R′ can be substituents including about 8 to about 16 carbon atoms and n represents the number of repeat unit from about 5 to about 5000. In various embodiments, R and R′ can include at least one of linear alkyl group, linear alkyl group including one or more hetero atoms, and linear fluorinated alkyl group. In certain embodiments, the polymer (II) can include alkyl group selected from the group consisting of octyl, nonyl, decyl, undecyl, dodecyl, tridecyl, tetradecyl, pentadecyl, and hexadecyl. In some embodiments, R and R′ can be the same. In other embodiments, R and R′ can be different.

In various embodiments, the polymer (II) can have a number average molecular weight (Mₙ) ranging from about 5,000 to about 100,000 and a weight average molecular weight (M_{w}) ranging from about 6000 to about 250,000, as measured by gel permeation chromatography using polystyrene standard.

In some embodiments, the polymer (II) can be prepared by oxidative coupling polymerization of a monomer (I) in the presence of an oxidizing agent in a solvent, as shown below in scheme 1. In other embodiments, the polymer (II) can be prepared by zinc-mediated coupling polymerization of a symmetrical monomer (III), as shown in Scheme 2. In some other embodiments, the polymer (II) can be prepared by Suzuki coupling polymerization of a compound (IV) with a diboronic acid or its ester (VI), as shown in Scheme 3.

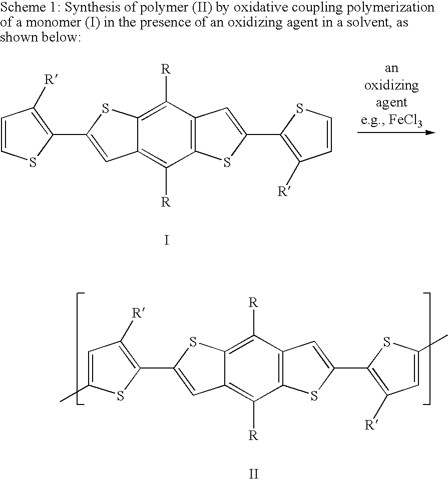

wherein R and R′ can be substituents including about 8 to about 16 carbon atoms.

In various embodiments, any suitable oxidizing agent including, but not limited to, FeCl₃, FeBr₃, Fe₂(SO₄)₃, Na₂S₂O₈, K₂S₂O₈, K₂Cr₂O₇, KMnO₄, KClO₃, MoCl₃, and the mixture thereof can be used for the polymerization of the symmetrical monomer (I). In some embodiments, the solvent can be selected from the group consisting of hydrocarbon solvents and halogenated hydrocarbon solvents. In certain embodiments, the halogenated hydrocarbon solvent can be selected from the group consisting of dichloromethane, chloroform, trichloroethane, tetrachloroethane, chlorobenzene, dichlorobenzene, trichlorobenzene, and the mixture thereof.

In various embodiments, the oxidative coupling polymerization can be carried out at a temperature in the range of about −40° C. to about 80° C. for a time in the range of about 15 minutes to about 48 hours.

The monomer (I) can be formed using any suitable method. An exemplary method is shown below in scheme 4:

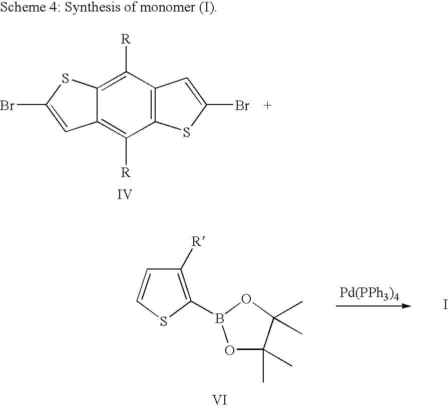

wherein R and R′ can be substituents including about 8 to about 16 carbon atoms and n represents the number of repeat unit from about 5 to about 5000. In certain embodiments, the polymer (II) can include alkyl group selected from the group consisting of octyl, nonyl, decyl, undecyl, dodecyl, tridecyl, tetradecyl, pentadecyl, and hexadecyl. In some embodiments, R and R′ can be the same. In other embodiments, R and R′ can be different. The compounds (IV) and (VI) can be prepared by any suitable method. In some embodiments, the compound 2,6-dibromo-4,8-didodeclybenzo[1,2-b;4,5;b′]dithiophene (IV) can be synthesized according to the procedure disclosed by H. Pan, Y. Li, Y. Wu, P. Liu, B. S. Ong, S. Zhu, G. Xu, in Chem. Mater., 2006, 18, 14, 3237, the disclosure of which is hereby incorporated by reference in its entirety. In other embodiments, the compound 3-dodecylthiophene-2-boronic acid pinacol ester (VI) can be synthesized according to the procedure described by Ong B S, Pan H L, Li Y N, Wu Y L, Liu P, in U.S. patent application Ser. No. 11/586,449, the disclosure of which is hereby incorporated by reference in its entirety.

Referring to the polymer (II), in some embodiments, the polymer (II) can be prepared by zinc-mediated coupling polymerization of a symmetrical monomer (III), as shown below in Scheme 2.

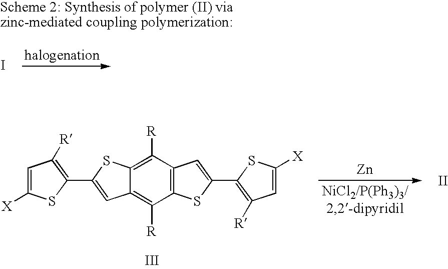

wherein X can be a halogen selected from the group consisting of Br, Cl, and I, and R and R′ can be substituents including about 8 to about 16 carbon atoms.

For an exemplary monomer (III), wherein X=Br, the monomer (III) can be obtained through bromination of the compound (I) using N-bromosuccinimide (NBS) or bromine (Br₂).

In other embodiments, the polymer (II) can be prepared by Stille or Suzuki-coupling polymerization of a compound (IV) with a bithiophene-2,5′-distannyl compound (V) or a diboronic acid or its ester (VI), as shown below in Scheme 3.

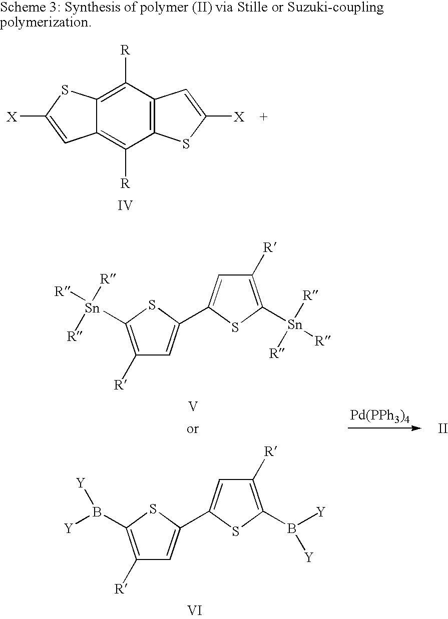

wherein X can be a halogen selected from the group consisting of Br, Cl, and I;
Y can be a hydroxyl (HO—) group or an alkoxy group such as, for example, CH₃O—, C₂H₅O—, C₃H₇O—, C₄H₉O—, —OCH₂CH₂O—, OCH₂CH₂CH₂O—, —OC(CH₃)₂C(CH₃)₂O—, and the like, and a mixture thereof
R and R′ can be substituents comprising about 8 to about 16 carbon atoms; and
R″ can be an alkyl group such as, for example, methyl, ethyl, propyl, butyl, and the like, and a mixture thereof.

FIG. 1 illustrates an exemplary thin film transistor 100, according to various embodiments of the present teachings. The exemplary thin film transistor 100 can include a substrate 110 and a dielectric layer 120 disposed over the substrate 110. The thin film transistor 100 can also include a source electrode 154 and a drain electrode 156 disposed over the dielectric layer 120. The thin film transistor 100 can further include a semiconductor layer 130 disposed over the dielectric layer 120, wherein the semiconductor layer 130 can include a polymer (II) having the formula:

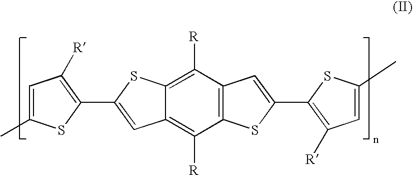

wherein R and R′ are substituents comprising about 8 to about 16 carbon atoms and n represents the number of repeating groups of from about 5 to about 5000. In various embodiments, R and R′ can include at least one of linear alkyl group, linear alkyl group including one or more hetero atoms, and linear fluorinated alkyl group.

The fabrication of the semiconductor layer 130 including the polymer (II) can be carried out by depositing the liquid composition including the polymer (II) on the substrate 110 using a liquid deposition technique at any suitable time prior to or subsequent to the formation of other optional layer or layers on the substrate 110. Thus, liquid deposition of the composition including the polymer (II) on the substrate 110 can occur either on a substrate 110 or on a substrate 110 already containing layered material, for example, a conductor layer and/or a dielectric layer. In various embodiments, the semiconductor layer 130 including the polymer (II) can have a thickness from about 10 nm to about 1 μm, and in some cases from about 40 nm to about 80 nm.

The phrase “liquid deposition technique” as used herein refers to deposition of a liquid composition using a liquid process such as, for example, liquid coating process and printing technique, where the liquid composition is a solution or a dispersion. The semiconductor composition including polymer (II) may be referred to as an ink when printing is used. Examples of liquid coating processes include, but are not limited to, spin coating, blade coating, rod coating, dip coating, and the like. Examples of printing techniques include, but are not limited to, lithography or offset printing, gravure, flexography, screen printing, stencil printing, inkjet printing, stamping (such as microcontact printing), and the like. Liquid deposition techniques deposits a layer of the liquid composition including the polymer (II) having a thickness ranging from about 5 nanometers to about 5 micrometers, and preferably from about 10 nanometers to about 100 nanometers.

In various embodiments, a thermal annealing process at a temperature from about 80° C. to about 200° C. and in some cases from about 120° C. to about 150° C. can be carried out after the deposition of the semiconductor layer 130 including the polymer (II). The thermal annealing process can improve the mobility of the semiconductor in an electronic device such as the thin film transistor 100. However, to achieve low-cost roll-to-roll processing, polymer semiconductors requiring no post-deposition thermal annealing step are desired. In some embodiments, the semiconductor layer 130 including the polymer (II) does not require a thermal annealing step after the liquid deposition of the semiconductor layer 130 including the polymer (II).

Any suitable material can be selected for the substrate 110, such as, for example, silicon material inclusive of various appropriate forms of silicon, a glass plate, a plastic film or a sheet, and the like depending on the intended applications. For structurally flexible devices, a plastic substrate, such as, for example, polyester, polycarbonate, polyimide sheets, and the like, can be selected. The substrate 110 can have a thickness from about 10 μm to over 10 mm, and in some cases with from about 50 μm to about 100 μm, especially for a flexible plastic substrate, and in other cases from about 1 mm to about 10 mm for a rigid substrate such as glass or silicon.

The dielectric layer 120 can include any suitable material, such as, for example, an inorganic material, an organic polymer, or an organic-inorganic composite. Exemplary inorganic materials include, but are not limited to, silicon oxide, silicon nitride, aluminum oxide, barium titanate, barium zirconate titanate, and the like. Exemplary organic polymers include, but are not limited to, polyesters, polycarbonates, poly(vinyl phenol), polyimides, polystyrene, poly(methacrylate)s, poly(acrylate)s, epoxy resin, and the like. Exemplary organic-inorganic composite include, but are not limited to nanosized metal oxide particles dispersed in polymers such as polyester, polyimide, epoxy resin and the like. The dielectric layer 120 can have a thickness from about 10 nm to about 1 μm, and in some cases from about 100 nm to about 500 nm. One of ordinary skill in the art would know that the thickness of the dielectric layer 120 can also depend upon the dielectric constant of the dielectric material used. For example, for a dielectric layer 120 including a dielectric material having a dielectric constant of at least about 3, a suitable dielectric thickness of about 300 nm can provide a desirable capacitance, for example, of about 10⁻⁹ to about 10⁻⁷ F/cm².

Referring back to FIG. 1, the thin film transistor 100 can also include a gate electrode 152 disposed over the substrate 110. In certain embodiments, the gate electrode 152 can be included in the substrate 110, in the dielectric layer 120, and the like throughout. The gate electrode 152 can be a thin metal film, a conducting polymer film, a conducting film generated from a conducting ink or paste, or the substrate itself, for example heavily doped silicon. Exemplary gate electrode materials include, but are not limited to, aluminum, gold, chromium, indium tin oxide, conducting polymers, such as polystyrene sulfonate-doped poly(3,4-ethylenedioxythiophene) (PSS/PEDOT), a conducting ink/paste comprised of carbon black/graphite or colloidal silver dispersion contained in a polymer binder, such as ELECTRODAG® available from Acheson Colloids Company and silver filled electrically conductive thermoplastic ink available from Noelle Industries, and the like. The gate electrode 152 can be deposited by any suitable method, such as, for example, vacuum evaporation, sputtering of metals or conductive metal oxides, coating from conducting polymer solutions or conducting inks or dispersions by spin coating, casting or printing. The gate electrode 152 can have a thickness from about 10 nm to about 10 μm, and in some cases, such as for metal films from about 10 nm to about 200 nm, and in other cases, such as for polymer conductors from about 1 μm to about 10 μm.

As shown in FIG. 1, the thin film transistor 100 can also include a source electrode 154 and a drain electrode 156. In some embodiments, the semiconductor layer 130 can be disposed over and between the source electrode 154 and the drain electrode 156. The source electrode 154 and the drain electrode 156 can be fabricated from any suitable material which can provide a low resistance ohmic contact to the semiconductor layer 130. Exemplary materials suitable for use as the source electrode 154 and the drain electrode 156 include gold, nickel, aluminum, platinum, conducting polymers, and conducting inks. The source electrode 154 and the drain electrode 156 can have thickness from about 40 nm to about 1 μm and in some cases from about 100 nm to about 400 nm. In various embodiments, the source electrode 154 can grounded and a bias voltage of about 0 volt to about −80 volts can be applied to the drain electrode 156 to collect the charge carriers transported across a semiconductor channel when a voltage of about +10 volts to about −80 volts can be applied to the gate electrode 152. In various embodiments, the semiconductor channel can have a width from about 10 μm to about 5 mm and in some cases from about 100 μm to about 1 mm. In other embodiments, the semiconductor channel can have a length about 1 μm to about 1 mm and in some cases from about 5 μm to about 100 μm.

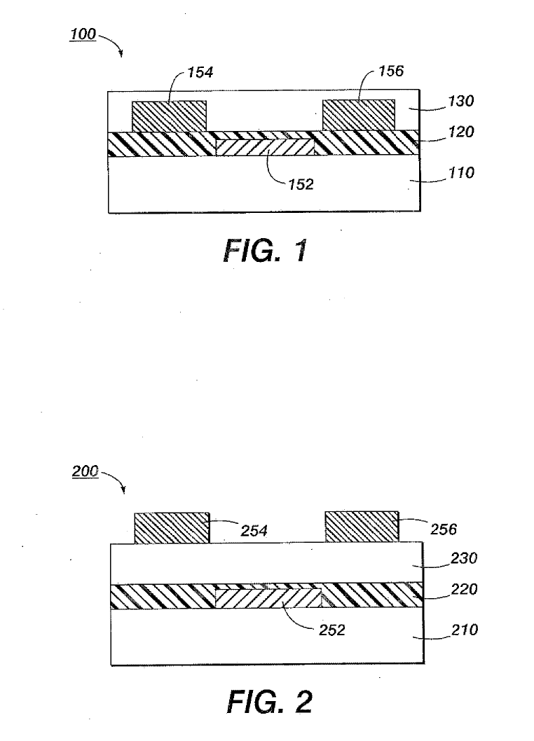

FIG. 2 schematically illustrates another exemplary thin film transistor 200 including a substrate 210, a gate electrode 252 disposed over the substrate 210, a dielectric layer 220 disposed over the substrate 210, a semiconductor layer 230, including polymer (II) of the present invention disposed over the dielectric layer 220, and a source electrode 254, and a drain electrode 256 disposed over semiconductor layer 230.

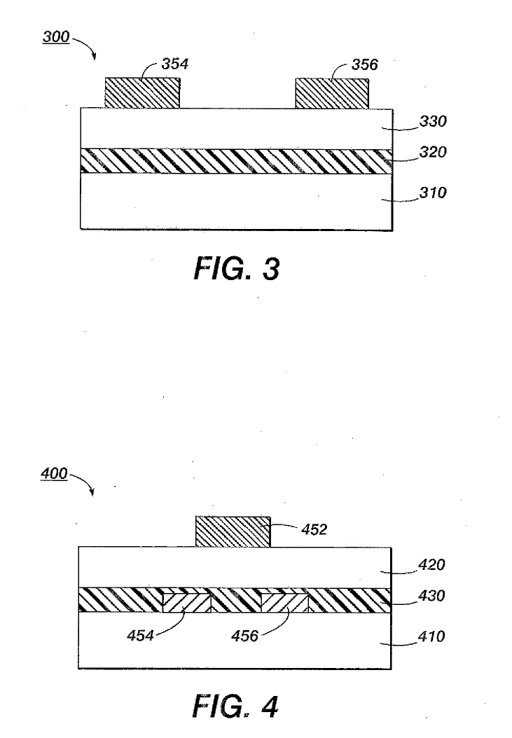

FIG. 3 schematically illustrates yet another exemplary thin film transistor 300 including a heavily n-doped silicon wafer 310, which can act as a gate electrode, a thermally grown silicon oxide dielectric layer 320 over the heavily n-doped silicon wafer 310, a semiconductor layer 330 including polymer (II) of the present invention over the dielectric layer 320, and a source electrode 354 and a drain electrode 356 disposed over the semiconductor layer 330.

FIG. 4 schematically illustrates another exemplary thin film transistor 400 including a substrate 410, a source electrode 454, and a drain electrode 456 disposed over the substrate, a dielectric layer 420 disposed over the substrate 410 and around the source electrode 454 and the drain electrode 456, a semiconductor layer 430 including polymer (II) of the present invention disposed over the dielectric layer 420, and a gate electrode 452 disposed over the semiconductor layer 430.

In various embodiments, an optional protective layer (not shown), such as a suitable polymer like a polyester, can be disposed on top of each of the exemplary thin film transistors 100, 200, 300, 400, as shown in FIGS. 1-4. For the thin film transistor 400, as shown in FIG. 4, the dielectric layer 420 can also function as a protective layer.

According to various embodiments, there is an electronic device (not shown) including the polymer (II) having the formula:

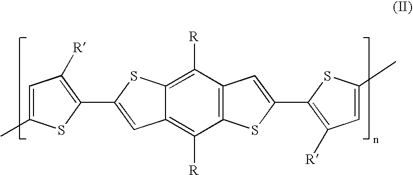

wherein R and R′ are substituents comprising about 8 to about 16 carbon atoms and n represents the number of repeat unit from about 5 to about 5000. In various embodiments, R and R′ can include at least one of linear alkyl group, linear alkyl group including one or more hetero atoms, and linear fluorinated alkyl group.

In various embodiments, the electronic device can include alkyl group selected from the group consisting of octyl, nonyl, decyl, undecyl, dodecyl, tridecyl, tetradecyl, pentadecyl, and hexadecyl.

In some embodiments, the electronic device can include the polymer (II) prepared by one or more of oxidative coupling polymerization of the monomer (I) in the presence of an oxidizing agent in a solvent, as shown in Scheme 1, zinc-mediated coupling polymerization of the symmetrical monomer (III), as shown in Scheme 2, and Suzuki coupling polymerization of the compound (IV) with a diboronic acid or its ester (VI), as shown in Scheme 3.

In some embodiments, the polymer (II) in the electronic device can be deposited using a liquid deposition technique including a liquid coating process. In other embodiments, the polymer (II) in the electronic device can be deposited using a liquid deposition technique including a printing technique.

According to various embodiments, there is a method of making an electronic device. The method can include providing a solution of polymer (II) in an aromatic solvent, wherein the polymer (II) is of the formula shown in scheme 1, wherein the R and R′ groups can contain from about 8 to about 16 carbon atoms and wherein n represents the number of segments. In various embodiments, the R and R′ groups can be an alkyl group, an alkenyl group, an alkynyl group, an alkyl group substituted with a cycloalkyl group(s) which may contain a hetero atom(s) in the ring thereof, an alkyl group substituted with an aryl group(s), or an alkyl group substituted with a heteroaryl group. The method can also include providing a substrate and depositing a thin layer of polymer (II) over the substrate. In some embodiments, the method can further include forming a dielectric layer over the substrate, depositing a thin layer of polymer (II) over the dielectric layer, and forming at least one metal electrode over the thin layer of polymer (II).

Examples are set forth herein below and are illustrative of different amounts and types of reactants and reaction conditions that can be utilized in practicing the disclosure. It will be apparent, however, that the disclosure can be practiced with other amounts and types of reactants and reaction conditions than those used in the examples, and the resulting devices various different properties and uses in accordance with the disclosure above and as pointed out hereinafter.

### EXAMPLES

### Example 1

### Synthesis of 4,8-Didodecyl-2,6-bis-(3-dodecyl-thiophen-2-yl)-benzo[1,2-b;4,5-b′]dithiophene (I)

About 2.0 gram of 2,6-dibromo-4,8-didodeclybenzo[1,2-b;4,5-b′]dithiophene (III), about 2.76 g of 3-dodecylthiophene-2-boronic acid pinacol ester (IV), and about 25 ml of toluene were added to a 250 ml 3-necked reaction flask. The compound 2,6-dibromo-4,8-didodeclybenzo[1,2-b;4,5;b′]dithiophene (III) was synthesized according to the procedure disclosed by H. Pan, Y. Li, Y. Wu, P. Liu, B. S. Ong, S. Zhu, G. Xu, in Chem. Mater., 2006, 18, 14, 3237, the disclosure of which is hereby incorporated by reference in its entirety. The compound 3-dodecylthiophene-2-boronic acid pinacol ester (IV) was synthesized according to the procedure described by Ong B S, Pan H L, Li Y N, Wu Y L, Liu P, in U.S. patent application Ser. No. 11/586,449, the disclosure of which is hereby incorporated by reference in its entirety. The resulting mixture was thoroughly stirred and purged with argon. Then, about 0.07 g of tetrakis(triphenylphosphine palladium(0)) (Pd(Ph₃P)₄), about 0.72 g of Aliquat® in about 10 ml of toluene, and about 8.4 ml of 2 M aqueous Na₂CO₃ were added to the mixture to form a reaction mixture. The reaction mixture was stirred at about 105° C. for about 72 hours. After cooling to room temperature in the range of about 23° C. to about 26° C., 200 ml of toluene was added and the resulting organic layer was washed with de-ionized water three times in a separatory funnel, dried over anhydrous MgSO₄, and filtered. After removing the solvent, the remaining solid was purified by column chromatography on silica gel (eluent: hexaneltoluene, 7/1, v/v) and recrystallized from 2-propanol to yield yellow needle-like crystals. Yield: 2.4 g (80%).

¹H NMR(CDCl₃, 300 MHz, ppm): δ 7.44 (s, 2H), 7.28 (d, J=5.1 Hz, 2H), 7.01 (d, J=5.1 Hz, 2H), 3.16 (t, 4H), 2.90 (t, 4H), 2.90 (t, 4H), 1.88 (m, 4H), 1.72 (m, 4H), 1.26 (br, 72H)₇ 0.89 (t, 6H); ¹³C NMR (CDCl₃, 300 MHz, ppm): δ 141.15, 137.99, 136.72, 136.15, 131.58, 128.84, 125.04, 120.56, 33.82, 32.34, 31.27, 30.44, 30.12, 30.08, 30.05, 29.99, 29.94, 29.87, 29.78, 23.10, 14.52

### Example 2

### Synthesis of Poly(4,8-didodecyl-2,6-bis-(3-dodecyl-thiophen-2-yl)-benzo[1,2-b;4,5-b′]dithiophene) (II), (PBBDT-12)

About 0.4 g of the above prepared 4,8-didodecyl-2,6-bis-(3-dodecyl-thiophen-2-yl)-benzo[1,2-b;4,5-b′]dithiophene was added to about 10 ml of chlorobenzene to form a solution. This solution was then added drop-wise through a dropping funnel to a well-stirred mixture of about 0.4 g of FeCl₃ (iron(III)chloride) in about 10 ml of chlorobenzene in a 50 ml round-bottom flask under an argon atmosphere for a period about 1 minute. The resulting mixture was stirred at room temperature in the range of about 23° C. to about 26° C. for about 4 hours under a blanket of argon. Then, about 15 ml of chlorobenzene was added and about 200 ml of methanol was added to the resulting solution to remove the FeCl₃. The mixture was ultrasonicated for about 2 minute and then stirred at room temperature for about 1 hour. The polymer was filtered out and added into a well stirred solution of about 200 ml methanol and about 50 ml of aqueous ammonia (30%). The mixture was ultrasonicated for about 30 minutes again and then stirred at room temperature for overnight. A dark red precipitate was obtained after filtration, which was purified by Soxhlet extraction with methanol for about 4 hours, and heptane for about 24 hours. The polymer was further extracted using chlorobenzene for about 4 hours to obtain a red solution. The solvent was removed to get about 0.32 g (80%) of poly(4,8-didodecyl-2,6-bis-(3-dodecyl-thiophen-2-yl)-benzo[1,2-b;4,5-b′]dithiophene) (PBBDT-12-B) as a dark red solid. High-temperature GPC analysis of the PBBDT-12-A done at 100° C. with 1,3,5-trichlorobenzene as an eluent gave Mₙ=22,600 and M_{w}=50,100 against polystyrene standards. Melting point of the PBBDT-12-B as determined by DSC analysis was 274° C.

### Comparative Example 1

### Synthesis of Poly(4,8-dihexyl-2,6-bis-(3-hexyl-thiophen-2-yl)-benzo[1,2-b:4,5-b′]dithiophene) (PBBDT-6)

The synthetic procedure was described by Ong B S, Pan H L, Li Y N, Wu Y L, Liu P, in U.S. patent application Ser. No. 11/586,449, the disclosure of which is hereby incorporated by reference in its entirety. A solution of about 0.5 grams of 4,8-dihexyl-2,6-bis-(3-hexyl-thiophen-2-yl)-benzo[1,2-b:4,5-b′]dithiophene in about 5 milliliters of chlorobenzene was added drop-wise through a dropping funnel to a well-stirred mixture of about 0.59 grams of FeCl₃ (iron(III) chloride) in about 5 milliliters of chlorobenzene in a 50 milliliter round-bottom flask under an argon atmosphere over a period of about 1 minute with droplet through the syringe. The green solution turned black immediately after added to the FeCl₃ solution. About 10 milliliters of chlorobenzene was used to clean the glassware. The resulting mixture was heated to about 65° C. and maintained at this temperature for about 48 hours under a blanket of argon. After cooling down to room temperature, about 15 milliliters of chlorobenzene were added, and the solution was poured into about 200 milliliters of methanol. The mixture was ultrasonicated for about 20 minutes before stirred at room temperature for about 1 hour. The polymer was filtered out and added into a well stirred mixture of about 200 milliliters of methanol and about 50 milliliters of ammonia aqueous solution (about 30 percent). The mixture was ultrasonicated for about 5 minutes and then stirred at room temperature for about 3 days. A dark red solid was obtained after filtration, which was purified by Soxhlet extraction with methanol for about 4 hours, and heptane for about 24 hours. Then chlorobenzene was used to extract polymer for 16 hours. Removal of solvent and drying in vacuum provided about 60 milligrams (about 12%) of brown powder. The molecular weight and distribution were measured by using high temperature GPC at about 100° C., with Mₙ=16,300, M_{w}=62,100, and polydispersity about 3.81 against polystyrene standards.

### Example 3

### Device Fabrication and Characterization

A top-contact thin film transistor 300, an example of which is schematically illustrated in FIG. 3, was fabricated for each of the two polymer semiconductors, PBBDT-12 and PBBDT-6, the Example 2 and the Comparative Example 1 respectively.

Each of the thin film transistors 300 included an n-doped silicon wafer as a substrate 310 and a thermally grown silicon oxide layer having a thickness of about 200 nm as a dielectric layer 320 over the substrate 310. The n-doped silicon wafer also functioned as the gate electrode and had a capacitance of about 32 nF/cm². The thin film transistors 300 were fabricated under ambient conditions without any precautions being taken to exclude the materials selected and device from exposure to ambient oxygen, moisture, or light. The surface of the n-doped silicon wafer was modified with a SAM silane interfacial layer by immersing the plasma cleaned n-doped silicon wafer in a 0.1 M solution of dodecyltrichlorosilane in toluene at 60° C. for about 20 minutes. About 10 mg of each of PBBDT-12 and PBBDT-6 was dissolved in about 1 g of dichorobenzene with heating to form two solutions, PBBDT-12 solution and PBBDT-6 solution. Each of these two solutions was then filtered through a 0.45 mm syringe filter and spin coated onto a surface modified n-doped silicon wafer at about 1000 rpm for about 90 seconds. After drying off the solvent, gold source and drain electrodes were deposited by evaporation through a shadow mask on top of the semiconductor polymer layer 330 including one of PBBDT-12 or PBBDT-6 to complete the formation of thin film transistor 300.

The evaluation of the field-effect transistor performance was accomplished in a black box under ambient conditions using a Keithley 4200 SCS semiconductor characterization system. The carrier mobility, p, was calculated from the data in the saturated regime (gate voltage, V_{G}<source-drain voltage, V_{D}) according to the equation (1)

I_{D}=Cᵢμ(W/2L)(V_{G}−V_{T})² (1)

where I_{D} is the drain current at the saturated regime; W and L are, respectively, the semiconductor channel width and length; Cᵢ is the capacitance per unit area of the gate dielectric layer, and V_{G} and V_{T} are, respectively, the gate voltage and threshold voltage. V_{T} of the device was determined from the relationship between the square root of I_{D} at the saturated regime and V_{G} of the device was determined by extrapolating the measured data to I_{D}=0.

Another property of a field-effect transistor is its current on-to-off ratio (Iₒₙ/I_{off}). This is the ratio of the saturation source-drain current when the gate voltage V_{G} is equal to or greater than the drain voltage V_{D} to the source-drain current when the gate voltage V_{G} is zero.

The transfer and output characteristics of the devices revealed that poly(4,8-didodecyl-2,6-bis-(3-dodecyl-thiophen-2-yl)-benzo[1,2-b:4,5-b′]dithiophene) (PBBDT-12) and poly(4,8-dihexyl-2,6-bis-(3-hexyl-thiophen-2-yl)-benzo[1,2-b:4,5-b′]dithiophene) (PBBDT-6) were p-type semiconductors. Using transistors with a dimension of W=about 5,000 μm and L=about 40 to about 90 μm, the following average properties from at least five transistors were obtained.

TABLE 1
Thin film transistor properties of PBBDT-12 and PBBDT-6

| Polymer | Mobility, cm²V⁻¹s⁻¹ | Iₒₙ/I_{off} |
|---|---|---|
| PBBDT-12 (Example 2) | 0.31-0.36 | 10⁶-10⁷ |
| PBBDT-6 (Comparative | 0.14-0.20 | 10⁴-10⁶ |
| Example 1) | | |

As shown in Table 1, the thin film transistor device including PBBDT-12 as a semiconductor layer showed higher mobility and higher current on-to-off ratio than thin film transistor device including PBBDT-6 as a semiconductor layer. It was also observed that PBBDT-12 has a better solubility in dichlorobenzene and formed more uniform films compared with PBBDT-6. In addition, the synthetic yield of PBBDT-12 (about 80%) was substantially higher than that of PBBDT-6 (about 12%).

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

While the invention has been illustrated respect to one or more implementations, alterations and/or modifications can be made to the illustrated examples without departing from the spirit and scope of the appended claims. In addition, while a particular feature of the invention may have been disclosed with respect to only one of several implementations, such feature may be combined with one or more other features of the other implementations as may be desired and advantageous for any given or particular function. Furthermore, to the extent that the terms “including”, “includes”, “having”, “has”, “with”, or variants thereof are used in either the detailed description and the claims, such terms are intended to be inclusive in a manner similar to the term “comprising.”

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A polymer having the formula: 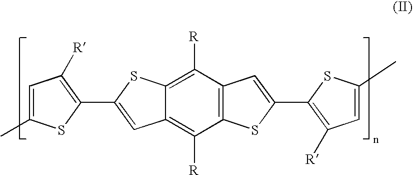
wherein R and R′ are substituents comprising about 8 to about 16 carbon atoms; and
n represents the number of repeat unit from about 5 to about 5000.

2. The polymer of claim 1, wherein R and R′ comprises at least one of linear alkyl group, linear alkyl group comprising one or more hetero atoms, and linear fluorinated alkyl group.

3. The polymer of claim 1, wherein the R and R′ groups are selected from the group consisting of octyl, nonyl, decyl, undecyl, dodecyl, tridecyl, tetradecyl, pentadecyl, and hexadecyl.

4. A method of forming the polymer of claim 1, wherein the polymer is prepared by oxidative coupling polymerization of a monomer (I) in the presence of an oxidizing agent in a solvent: 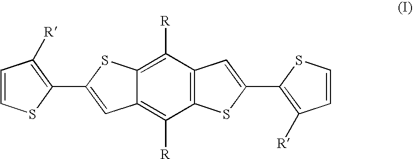
wherein R and R′ are substituents comprising about 8 to about 16 carbon atoms.

5. The method of claim 4, wherein the oxidizing agent is selected from the group consisting of FeCl₃, FeBr₃, Fe₂(SO₄)₃, Na₂S₂O₈, K₂S₂O₈, K₂Cr₂O₇, KMnO₄, KClO₃, MoCl₃, and the mixture thereof.

6. The method of claim 4, wherein the solvent is selected from the group consisting of hydrocarbon solvents and halogenated hydrocarbon solvents.

7. The method of claim 6, wherein the halogenated hydrocarbon solvent is selected from the group consisting of dichloromethane, chloroform, trichloroethane, tetrachloroethane, chlorobenzene, dichlorobenzene, trichlorobenzene, and the mixture thereof.

8. The method of claim 4, wherein the oxidative coupling polymerization is carried out at a temperature in the range of about −40° C. to about 80° C. for a time in the range of about 15 minutes to about 48 hours.

9. A method of forming the polymer of claim 1, wherein the polymer is prepared by zinc-mediated coupling polymerization of a symmetrical monomer (III) having the formula: 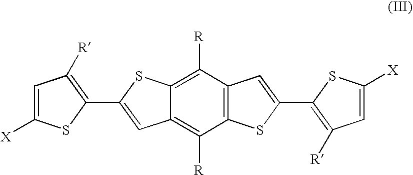
wherein X is a halogen selected from the group consisting of Br, Cl, and I; and
R and R′ are substituents comprising about 8 to about 16 carbon atoms.

10. A method of forming the polymer of claim 1, wherein the polymer is prepared by Stille coupling polymerization of compound (IV) with compound (V): 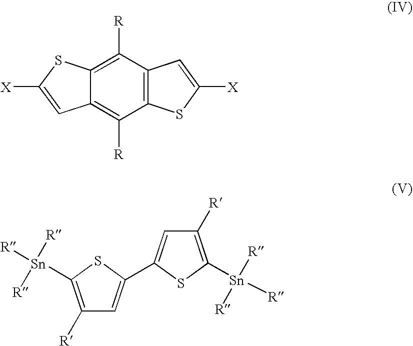
wherein X is a halogen selected from the group consisting of Br, Cl, and I;
R and R′ are substituents comprising about 8 to about 16 carbon atoms; and
R″ is an alkyl group selected from the group consisting of methyl, ethyl, propyl, and butyl.

11. A method of forming the polymer of claim 1, wherein the polymer is prepared by Suzuki coupling polymerization of compound (IV) with compound (VI): 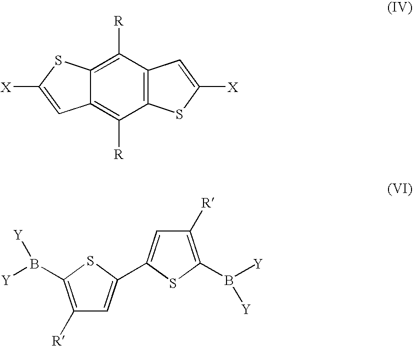
wherein X is a halogen selected from the group consisting of Br, Cl, and I;
Y selected from the group consisting of HO—, CH₃O—, C₂H₅O—, C₃H₇O—, C₄H₉O—, —OCH₂CH₂O—, OCH₂CH₂CH₂O—, and —OC(CH₃)₂C(CH₃)₂O—; and
R and R′ are substituents comprising about 8 to about 16 carbon atoms.

12. An electronic device comprising a polymer (II) having the formula: 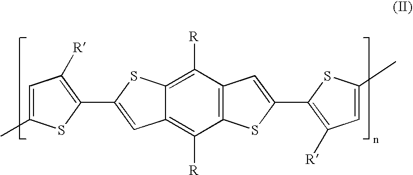
wherein R and R′ are substituents comprising about 8 to about 16 carbon atoms; and
n represents the number of repeat unit from about 5 to about 5000.

13. The electronic device of claim 12, wherein R and R′ comprises at least one of linear alkyl group, linear alkyl group comprising one or more hetero atoms, and linear fluorinated alkyl group.

14. The electronic device of claim 12, wherein the R and R′ groups are selected from the group consisting of octyl, nonyl, decyl, undecyl, dodecyl, tridecyl, tetradecyl, pentadecyl, and hexadecyl.

15. The electronic device of claim 12, wherein the polymer (II) is deposited using a liquid deposition technique comprising a liquid coating process.

16. The electronic device of claim 12, wherein the polymer (II) is deposited using a liquid deposition technique comprising a printing technique.

17. A thin film transistor comprising:
a substrate;
a dielectric layer disposed over the substrate;
a source electrode and a drain electrode disposed over the substrate; and
a semiconductor layer disposed over the substrate, the semiconductor layer comprising a polymer (II) having the formula: 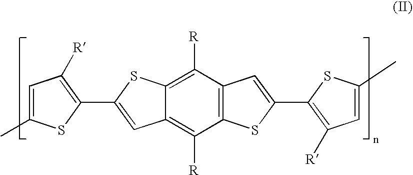
wherein R and R′ are substituents comprising about 8 to about 16 carbon atoms; and
n represents the number of repeating groups of from about 5 to about 5000.

18. The thin film transistor of claim 17, wherein R and R′ comprises at least one of linear alkyl group, linear alkyl group comprising one or more hetero atoms, and linear fluorinated alkyl group.

19. The thin film transistor of claim 17, wherein the R and R′ groups are selected from the group consisting of octyl, nonyl, decyl, undecyl, dodecyl, tridecyl, tetradecyl, pentadecyl, and hexadecyl.

20. The thin film transistor of claim 17, wherein the polymer (II) is prepared by oxidative coupling polymerization of a monomer (I) in the presence of an oxidizing agent in a solvent: 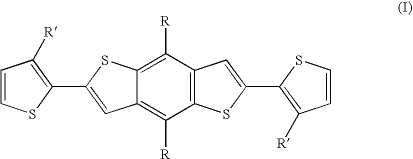
wherein R and R′ are substituents comprising about 8 to about 16 carbon atoms.

21. The thin film transistor of claim 20, wherein the oxidizing agent is selected from a group consisting of FeCl₃, FeBr₃, Fe₂(SO₄)₃, Na₂S₂O₈, K₂S₂O₈, K₂Cr₂O₇, KMnO₄, KClO₃, MoCl₃, and the mixture thereof.

22. The thin film transistor of claim 17, wherein the polymer (II) is deposited using a liquid deposition technique comprising a liquid coating process.

23. The electronic device of claim 17, wherein the polymer (II) is deposited using a liquid deposition technique comprising a printing technique.

24. The thin film transistor of claim 17 having a mobility greater than about 0.2 cm²V⁻¹s⁻¹ without thermal annealing.
